(19) United States
(12) Patent Application Publication
(10) Pub. No.: US 2025/0391827 A1
(43) Pub. Date: Dec. 25, 2025

(54) SEMICONDUCTOR PACKAGE AND MANUFACTURING METHOD THEREOF

(71) Applicant: SAMSUNG ELECTRONICS CO., LTD., SUWON-SI (KR)

(72) Inventors: Choongbin YIM, SEOUL (KR); Jinwoo PARK, SEOUL (KR)

(73) Assignee: SAMSUNG ELECTRONICS CO., LTD., SUWON-SI (KR)

(21) Appl. No.: 19/311,888

(22) Filed: Aug. 27, 2025

Related U.S. Application Data
(63) Continuation of application No. 17/807,691, filed on Jun. 17, 2022, now Pat. No. 12,424,601.

(30) Foreign Application Priority Data
Jun. 18, 2021 (KR) 10-2021-0079517

(51) Int. Cl. H01L 25/18; H01L 21/56; H01L 23/00; H01L 23/31; H01L 23/498

(52) U.S. Cl. CPC H01L 25/18; H01L 21/563; H01L 23/3121; H01L 23/49811; H01L 24/16; H01L 24/29; H01L 24/32; H01L 24/73; H01L 24/92; H01L 2224/16227; H01L 2224/2929; H01L 2224/29386; H01L 2224/32225; H01L 2224/73204; H01L 2224/92125

(57) ABSTRACT

A semiconductor package includes: a package substrate; a semiconductor chip mounted above the package substrate; a chip connection terminal arranged between the semiconductor chip and the package substrate; an adhesive layer arranged on the package substrate to cover a side and a top surface of the semiconductor chip and surrounding the chip connection terminal between the semiconductor chip and the package substrate; a molding layer arranged on the package substrate and surrounding the adhesive layer; an interposer including an interposer substrate mounted on the adhesive layer and the molding layer; and a conductive pillar arranged on the package substrate to surround the side of the semiconductor substrate and configured to penetrate the molding layer in a vertical direction and connect the package substrate to the interposer substrate.

### CROSS-REFERENCE TO RELATED APPLICATION

This application is a Continuation of U.S. patent application Ser. No. 17/807,691, filed on Jun. 17, 2022, which claims priority under 35 U.S.C. § 119 to Korean Patent Application No. 10-2021-0079517, filed on Jun. 18, 2021 in the Korean Intellectual Property Office, the disclosure of which is incorporated by reference herein in its entirety.

### BACKGROUND

The inventive concept relates to a semiconductor package, and more particularly, to a package-on-package type semiconductor package including a lower semiconductor package and an upper semiconductor package.

In accordance with the increase in the storage capacity of semiconductor chips, it is required to decrease the thickness and weight of semiconductor packages including semiconductor chips. In addition, researches for including semiconductor chips having various functions in such semiconductor packages and rapidly driving the semiconductor chips have been conducted. In response to such trend, researches have been conducted with respect to package-on-package type semiconductor packages having a structure in which an upper semiconductor package is mounted above a lower semiconductor package. For example, researches about methods of improving the reliability of package-on-package type semiconductor packages have been actively conducted.

### SUMMARY

According to an aspect of the inventive concept, there is provided a package-on-package (POP) type semiconductor package with improved structural reliability.

According to another aspect of the inventive concept, there is provided a PoP type semiconductor package with smaller thickness and weight.

According to another aspect of the inventive concept, there is provided a manufacturing method of a PoP type semiconductor package, whereby a manufacturing time period and manufacturing cost are reduced.

According to an example embodiment of the inventive concept, there is provided a semiconductor package including: a package substrate; a semiconductor chip mounted above the package substrate; a chip connection terminal arranged between the semiconductor chip and the package substrate and configured to connect the semiconductor chip and the package substrate; an adhesive layer arranged on the package substrate to cover a side and a top surface of the semiconductor chip and surrounding the chip connection terminal between the semiconductor chip and the package substrate; a molding layer arranged on the package substrate and surrounding the adhesive layer; an interposer including an interposer substrate mounted on the adhesive layer and the molding layer; and a conductive pillar arranged on the package substrate to surround the side of the semiconductor chip and configured to penetrate the molding layer in a vertical direction and connect the package substrate to the interposer substrate.

According to an example embodiment of the inventive concept, there is provided a package-on-package (POP) type semiconductor package including a lower semiconductor package and an upper semiconductor package. The lower semiconductor package includes: a package substrate; a lower semiconductor chip mounted above the package substrate; a chip connection terminal arranged between the semiconductor chip and the package substrate and configured to connect the semiconductor chip to the package substrate; a first adhesive portion arranged on a package substrate and surrounding the lower semiconductor chip, the first adhesive portion arranged between the package substrate and the lower semiconductor chip and surrounding the chip connection terminal; a second adhesive portion arranged at outside of a side of the semiconductor chip; and a third adhesive portion arranged above a top surface of the semiconductor chip; a lower molding layer arranged on the package substrate to surround the adhesive layer; an interposer including an interposer substrate mounted on the third adhesive portion of the adhesive layer and the lower molding layer; and a conductive pillar arranged on the package substrate to surround the side of the semiconductor chip and configured to penetrate the lower molding layer in a vertical direction and connect the package substrate to the interposer substrate, and the upper semiconductor package includes: a redistribution structure; an upper semiconductor chip mounted on the redistribution structure; and a package connection terminal arranged on the redistribution structure and configured to connect the upper semiconductor chip to the interposer substrate.

According to an example embodiment of the inventive concept, there is provided a manufacturing method of a semiconductor package, the method including: forming a semiconductor chip and a conductive pillar on a package substrate; fixing the semiconductor chip above the package substrate through the adhesive layer by heating and pressing the adhesive layer arranged between the semiconductor chip and the interposer provided on the semiconductor chip; connecting the interposer to the package substrate; and forming a molding layer on the outside of the adhesive layer.

According to an example embodiment of the inventive concept, the adhesive layer of the semiconductor package may include a material that becomes soft but does not completely dissolve or melt when heat is applied thereto. Accordingly, in a process of forming the adhesive layer on the package substrate, through fluidity of the adhesive layer, a space between the semiconductor chip and the package substrate and a space between the semiconductor chip and the interposer may be filled with the adhesive layer without voids. Accordingly, the structural reliability between the semiconductor chip and the package substrate and the structural reliability between the semiconductor chip and the interposer substrate may be improved.

In addition, according to an example embodiment of the inventive concept, the manufacturing method of the semiconductor package may fix the semiconductor chip and the package substrate and fix the semiconductor chip and the interposer through one adhesive layer. Accordingly, the manufacturing method of the semiconductor package according to an example embodiment of the inventive concept may reduce a manufacturing time period and manufacturing cost of the semiconductor package.

In addition, the semiconductor package manufactured by the manufacturing method of the semiconductor package according to an example embodiment of the inventive concept may have a smaller thickness and weight.

### BRIEF DESCRIPTION OF THE DRAWINGS

Embodiments of the inventive concept will be more clearly understood from the following detailed description taken in conjunction with the accompanying drawings in which:

FIG. 1 is a diagram of a semiconductor package according to an embodiment of the inventive concept;

FIG. 2 is a cross-sectional view of a region marked with II-II′ in FIG. 1;

FIG. 3 is a cross-sectional view of a semiconductor package according to a Comparative Example;

FIG. 4 is a cross-sectional view of a semiconductor package according to an example embodiment of the inventive concept;

FIG. 5 is a cross-sectional view of a semiconductor package according to an example embodiment of the inventive concept;

FIG. 6 is a cross-sectional view of a semiconductor package according to an example embodiment of the inventive concept;

FIG. 7 is a cross-sectional view of a semiconductor package according to an example embodiment of the inventive concept;

FIG. 8 is a cross-sectional view of a semiconductor package according to an example embodiment of the inventive concept;

FIG. 9 is an enlarged view of a region marked with “A” in FIG. 8;

FIG. 10 is a cross-sectional view of a semiconductor package according to an example embodiment of the inventive concept;

FIG. 11 is a cross-sectional view of a semiconductor package according to an example embodiment of the inventive concept;

FIG. 12 is a flowchart of a manufacturing method of a semiconductor package according to an example embodiment of the inventive concept; and

FIG. 13 through FIG. 18 are diagrams showing processes of a method of manufacturing a semiconductor package according to an example embodiment of the inventive concept.

### DETAILED DESCRIPTION OF THE EMBODIMENTS

Hereinafter, embodiments of the inventive concept will be described in detail with reference to the accompanying drawings.

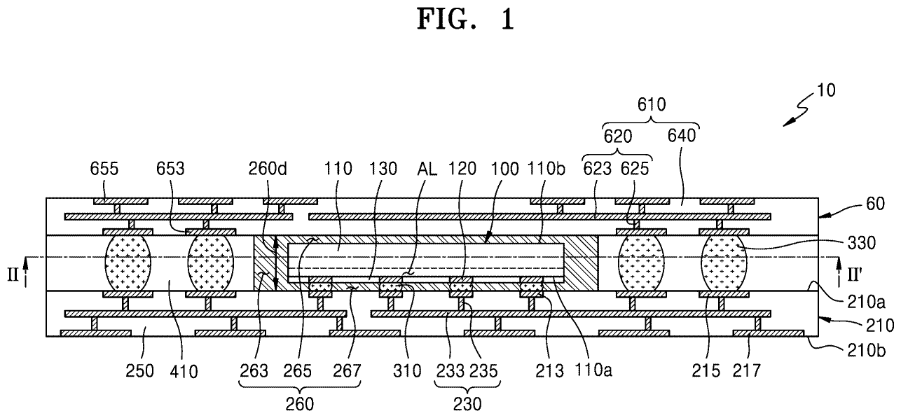

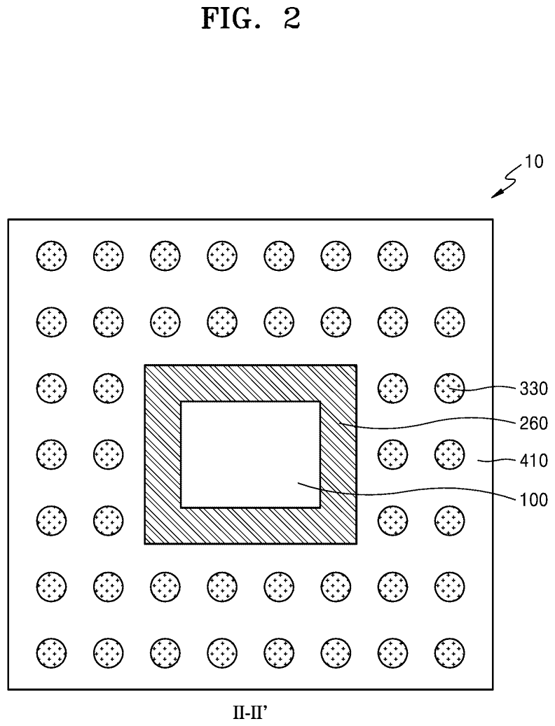

FIG. 1 is a diagram of a semiconductor package 10 according to an embodiment of the inventive concept. FIG. 2 is a cross-sectional view of a region marked with II-II′ shown in FIG. 1. The semiconductor package 10 shown in FIGS. 1 and 2 may include a lower semiconductor package forming a package-on-package (POP) type semiconductor package.

Referring to FIGS. 1 and 2, the semiconductor package 10 may include a package substrate 210, a semiconductor chip 100, an adhesive layer 260, a chip connection terminal 310, a conductive pillar 330, a molding layer 410, an interposer 60, and the like.

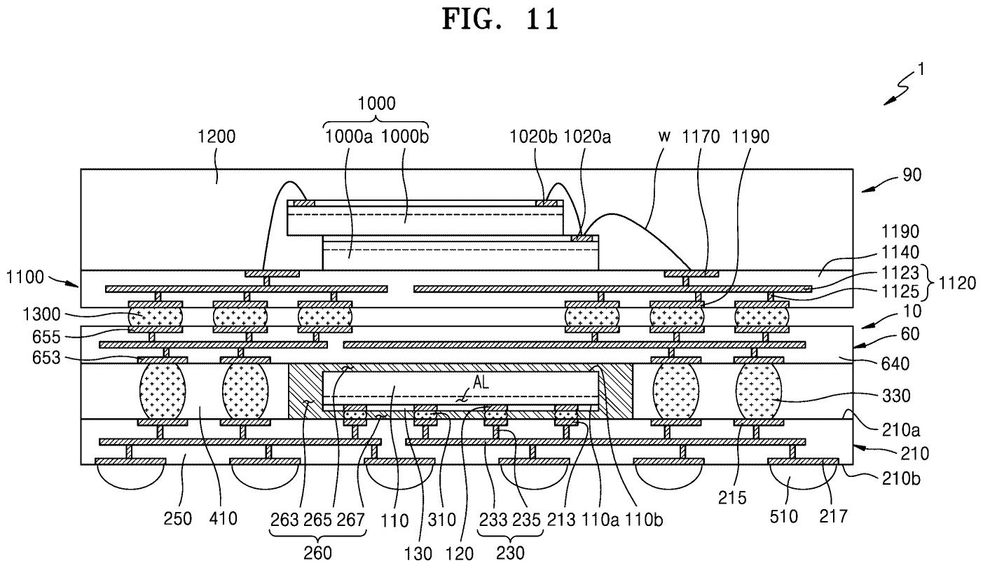

The package substrate 210 of the semiconductor package 10 may include a substrate for mounting the semiconductor chip 100 and connecting the semiconductor chip 100 to an external device. The semiconductor substrate 210 may have a top surface 210a and a bottom surface 210b. For example, the top surface 210a of the package substrate 210 may be a surface of the package substrate 210 above which the semiconductor chip 100 is mounted, and the bottom surface 210b may be a surface of the semiconductor chip 100 opposite to the top surface 210a, the surface to which an external connection terminal 510 (see FIG. 11) is attached.

In an example embodiment, the package substrate 210 may include a double-sided printed circuit board (double-sided PCB) including a first package substrate pad 213 and a second package substrate 215, which are on the top surface 210a, and a third package substrate pad 217 on the bottom surface 210b. However, the package substrate 210 is not limited to a structure and a material of a PCB, and may include various kinds of substrates such as a silicon substrate or a ceramic substrate.

In an example embodiment, the package substrate 210 may include a package substrate insulating layer 250, a package substrate pattern 230, the first package substrate pad 213, the second package substrate pad 215, and the third package substrate pad 217.

In an example embodiment, the package substrate insulating layer 250 may include an insulating layer surrounding the package substrate pattern 230 and forming an exterior of the package substrate 210. For example, the package substrate insulating layer 250 may include a solder resist material layer.

In an example embodiment, a material of the package substrate insulating layer 250 may include an oxide or a nitride. For example, the package substrate insulating layer 250 may include silicon oxide or silicon nitride. However, the material of the package substrate insulating layer 250 is not limited to the description.

In an example, embodiment, the package substrate pattern 230 may include a package substrate line pattern 233 extending in a horizontal direction in the package substrate insulating layer 250, and a package substrate via pattern 235 extending in a vertical direction in the package substrate insulating layer 250.

The horizontal direction may be defined as a direction parallel to a direction in which the top surface 210a and the bottom surface 210b of the package substrate 210 extend, and the vertical direction may be defined as a direction perpendicular to the horizontal direction and to the direction in which the top surface 210a and the bottom surface 210b of the package substrate 210 extend.

In an example embodiment, a material of the package substrate pattern 230 may include copper (Cu). However, the material of the package substrate pattern 230 is not limited thereto and may include a metal such as nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru), and an alloy thereof.

In an example embodiment, the first package substrate pad 213 may include a pad arranged on the top surface 210a of the package substrate 210 and configured to connect a plurality of individual devices in the semiconductor chip 100 to the package substrate pattern 230.

In addition, the second package substrate pad 215 may include a pad on the top surface 210a of the package substrate 210 to be arranged at the outside of the first package substrate pad 213, the pad configured to connect the conductive pillar 330 to the package substrate pattern 230.

In addition, the third package substrate pad 217 may be a pad arranged on the bottom surface 210b of the package substrate 210 and configured to connect the external connection terminal 510 (see FIG. 11) to the package substrate pattern 230.

The semiconductor chip 100 may be mounted above the top surface 210a of the package substrate 210. In an example embodiment, the semiconductor chip 100 may include a semiconductor substrate 110 having an active layer AL, a chip pad 102, a passivation layer 130, and the like.

In an example embodiment, the semiconductor chip 100 may include a memory semiconductor chip. The memory semiconductor chip may include, for example, a volatile memory semiconductor chip such as dynamic random access memory (DRAM) or static random access memory (SRAM), and may also include a non-volatile memory semiconductor chip such as phase-change random access memory (PRAM), magneto-resistive random access memory (MRAM), ferroelectric random access memory (FeRAM), or resistive random access memory (RRAM).

In an example embodiment, the semiconductor chip 100 may include a logic semiconductor chip. The logic semiconductor chip may include, for example, a logic semiconductor chip such as a central processor unit (CPU), a micro processor unit (MPU), a graphic processor unit (GPU), or an application processor (AP).

Although FIG. 1 illustrates that the semiconductor package 10 includes one semiconductor chip 100, the number of semiconductor chip 100 is not limited thereto, and the semiconductor chip 10 may include two or more semiconductor chips. For example, the semiconductor package 10 may include a plurality of semiconductor chips, and may include a system in package (SIP) type semiconductor in which a plurality of different semiconductor chips are electrically connected to one another and operate as a system.

The semiconductor substrate 110 of the semiconductor chip 100 may have a first surface 110a and a second surface 110b. The first surface 110a may include a surface of the semiconductor substrate 110 facing the package substrate 210, the surface to which the chip pad 120 is attached, and the second surface 110b may include a surface of the semiconductor substrate 110, the surface opposite to the first surface 110a.

In an example embodiment, the semiconductor substrate 110 may include silicon (Si). In addition, the semiconductor substrate 110 may include a semiconductor element such as germanium (Ge), or a compound semiconductor such as silicon carbide (SiC), gallium arsenide (GaAs), indium arsenide (InAs), and indium phosphide (InP). However, the material of the semiconductor substrate 110 is not limited to the materials stated above.

In an example embodiment, the semiconductor substrate 110 may have the active layer AL in a portion adjacent to the first surface 110a. In other words, the active layer AL of the semiconductor chip 100 may be formed in a portion of the semiconductor substrate 110a adjacent to the top surface 210a of the package substrate 210.

In an example embodiment, the active layer AL may include a plurality of various kinds of individual devices. For example, the plurality of individual devices may include various micro electronic devices, for example, a complementary metal-oxide semiconductor (CMOS) transistor, a metal-oxide-semiconductor field effect transistor (MOSFET), system large scale integration (system LSI), an image sensor such as a CMOS imaging sensor, a micro-electro-mechanical system (MEMS), an active element, a passive element, and the like.

The chip pad 120 of the semiconductor chip 100 may be a pad arranged on the first surface 110a of the semiconductor substrate 110 and electrically connected to the plurality of individual devices in the active layer AL. As shown in FIG. 1, a plurality of the chip pads 120 of the semiconductor chip 100 may be provided.

The passivation layer 130 of the semiconductor chip 100 may include a layer covering a side of the chip pad 120 on the first surface 110a of the semiconductor substrate 110. In addition, the passivation layer 130 may expose a bonding surface of the chip pad 120. The bonding surface of the chip pad 120 may include a surface of the chip pad 120 being in contact with the chip connection terminal 310.

In an example embodiment, a material of the passivation layer 130 may include silicon nitride (SiN). However, the material of the passivation layer 130 is not limited thereto and may include silicon oxynitride (SiON), silicon dioxide (SiO₂), silicon oxycarbonitride (SiOCN), silicon carbonitride (SiCN), or a combination thereof.

The chip connection terminal 310 may include a terminal arranged between the semiconductor chip 100 and the package substrate 210 and configured to electrically connect each of the plurality of individual devices in the semiconductor chip 100 to the package substrate pattern 230 of the package substrate 210. In detail, the chip connection terminal 310 may include a terminal arranged between the chip pad 120 of the semiconductor chip 100 and the first package substrate pad 213 of the package substrate 210, the terminal that electrically connects the chip pad 120 to the first package substrate pad 213.

In an example embodiment, the semiconductor chip 100 may be attached on the package substrate 210 through a flip-chip bonding process using the chip connection terminal 310.

In an example embodiment, the chip connection terminal 310 may include a solder ball of a metal material including at least any one of Sn, Ag, Cu, and Al.

The adhesive layer 260 may be arranged on the package substrate 210 to cover a top surface and a side of the semiconductor chip 100. In addition, the adhesive layer 260 may be configured to fix the semiconductor chip 100 above the package substrate 210.

In an example embodiment, the adhesive layer 260 may include a first adhesive portion 263, a second adhesive portion 265, and a third adhesive portion 267.

The first adhesive portion 263 may include a portion of the adhesive layer 260 that is arranged between the bottom surface of the semiconductor chip 100 and the top surface 210a of the package substrate 210 and surrounds the chip connection terminal 310. The second adhesive portion 265 may include a portion of the adhesive layer 260 arranged at the outside of the side of the semiconductor chip 100. In addition, the third adhesive portion 267 may include a portion of the adhesive layer 260 arranged between the top surface of the semiconductor chip 100 and a bottom surface of an interposer substrate 610.

In an example embodiment, the adhesive layer 260 may include a material that may become soft but does not completely dissolve or melted when heat is applied (for example, a b-stage state).

In an example embodiment, the adhesive layer 260 may include a binder material and a curing material. For example, the binder material of the adhesive layer 260 may include at least one of an acrylic polymer resin and an epoxy resin. In addition, the curing material of the adhesive layer 260 may include at least any one of an epoxy resin, a phenolic curing resin, and a phenoxy resin. In addition, the adhesive layer 260 may further include a curing catalyst, an additive such as silane coupling agent, and a filler such as silica.

In an example embodiment, the adhesive layer 260 may include a die attach film (DAF) that becomes soft but does not completely dissolve or melt when heat is applied thereto.

In an example embodiment, a thickness 260d of the adhesive layer 260 may be from about 50 micrometers to about 1000 micrometers. The thickness 260d of the adhesive layer 260 may be defined as a length in a vertical direction of the adhesive layer 260.

In addition, the thickness 260d of the adhesive layer 260 may be greater than a thickness of the semiconductor chip 100. For example, the thickness of the semiconductor chip 100 may be from about 20 micrometers to about 500 micrometers, and the thickness 260d of the adhesive layer 260 may have a value greater than the thickness of the semiconductor chip 100 in a range from about 50 micrometers to about 1000 micrometers.

In addition, the thickness 260d of the adhesive layer 260 may be from about 1.2 times to about 2.5 times the thickness of the semiconductor chip 100. When the thickness 260d of the adhesive layer 260 is less than about 1.2 times the thickness of the semiconductor chip 100, the thickness 260d of the adhesive layer 260 arranged between the semiconductor chip 100 and the interposer substrate 610 may decrease, and accordingly, the adhesion performance between the semiconductor chip 100 and the interposer substrate 610 may be degraded. In addition, when the thickness 260d of the adhesive layer 260 is greater than 2.5 times the thickness of the semiconductor chip 100, as a length in the vertical direction of the semiconductor package 10 relatively increases, it may be difficult to reduce the weight of the semiconductor package 10.

In an example embodiment, a bottom surface of the adhesive layer 260 may be on a same plane as the top surface 210a of the package substrate 210. In addition, a top surface of the adhesive layer 260 may be on a same plane as a top surface of the molding layer 410 and the bottom surface of the interposer substrate 610.

In an example embodiment, the molding layer 410 may be arranged on the package substrate 210 and surround a side of the adhesive layer 260. In addition, the molding layer 410 may be configured to prevent short-cut between the plurality of conductive pillars 330 and fix the interposer 60 on the adhesive layer 260.

In an example embodiment, a bottom surface of the molding layer 410 may be on a same plane as the top surface 210a of the package substrate 210, and a top surface of the molding layer 410 may be on a same plane as the bottom surface of the interposer substrate 610 and the top surface of the adhesive layer 260. In addition, a side of the molding layer 410 may be on a same plane as a side of the package substrate 210 and a side of the interposer substrate 610.

In an example embodiment, the material of the molding layer 410 may be different from the material of the adhesive layer 260. Accordingly, a boundary plane may be formed at a portion at which the molding layer 410 and the adhesive layer 260 are in contact with each other.

In an example embodiment, the molding layer 410 may include at least any one of a conductive polymer and an epoxy resin. For example, the molding layer 410 may include an epoxy molding compound (EMC).

The conductive pillar 330 may be arranged on the top surface 210a of the package substrate 210 to surround an edge of the semiconductor chip 100. In detail, the conductive pillar 330 may include a pillar formed of a conductive material arranged on the second package substrate pad 215 of the package substrate 210.

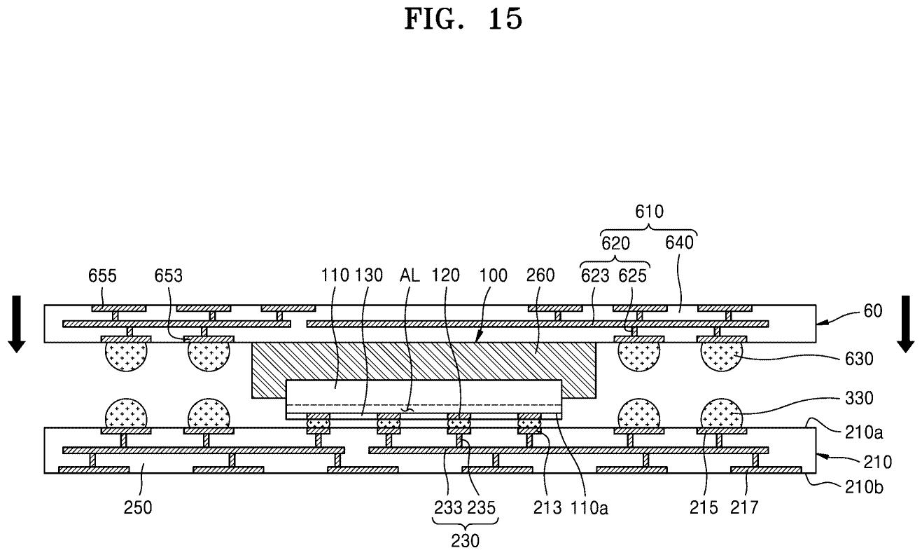

In an example embodiment, the conductive pillar 330 may be integrally formed with an interposer connection layer 630 (see FIG. 15) of the interposer 60 to be described later. In addition, a material of the conductive pillar 330 may include at least any one of Sn, Ag, Cu, and Al.

In an example, a cross-section in a horizontal direction of the conductive pillar 330 may have a circle shape. However, the shape of the cross-section in the horizontal direction of the conductive pillar 330 is not limited to the shape stated above. For example, the cross-section in the horizontal direction of the conductive pillar 330 may have a polygon shape.

In an example embodiment, a length in a vertical direction of the conductive pillar 330 may be substantially identical to a length in a vertical direction of the molding layer 410 and the length in the vertical direction of the adhesive layer 260.

The interposer 60 may include a structure provided to support an upper semiconductor package 90 (see FIG. 11) and electrically connect the upper semiconductor package 90 to the package substrate 210. The interposer 60 may include the interposer substrate 610, a first interposer substrate pad 653, and a second interposer substrate pad 655.

The interposer substrate 610 may include at least any one of a carrier, a PCB, and a wafer. In addition, the interposer substrate 610 may include an interposer substrate pattern 620 and an interposer insulating layer 640 surrounding the interposer substrate pattern 620.

The interposer substrate pattern 620 may include an interposer substrate line pattern 623 extending in a horizontal direction in the interposer insulating layer 640 and an interposer substrate via pattern 625 extending in a vertical direction in the interposer insulating layer 640.

A material of the interposer substrate pattern 620 may include Cu. However, the material of the interposer substrate pattern 620 is not limited thereto and may include a metal such as Ni, Au, Ag, Al, W, Ti, Ta, In, Mo, Mn, Co, Sn, Mg, Re, Be, Ga, and Ru, or an alloy thereof.

The interposer insulating layer 640 may include a layer formed of a conductive material surrounding the interposer substrate pattern 620. In addition, the interposer insulating layer 640 may form an exterior of the interposer substrate 610. In an example embodiment, the material of the interposer insulating layer 640 may include an oxide or a nitride. For example, the interposer insulating layer 640 may include silicon oxide or silicon nitride.

The first interposer substrate pad 653 may include a pad arranged on the bottom surface of the interposer substrate 610 and configured to connect the interposer substrate pattern 620 to the conductive pillar 330. In addition, the second interposer substrate pad 655 may include a pad arranged on a top surface of the interposer substrate 610 and configured to connect the interposer substrate pattern 620 to a package connection terminal 1300 (see FIG. 11) of the upper semiconductor package 90 (see FIG. 11).

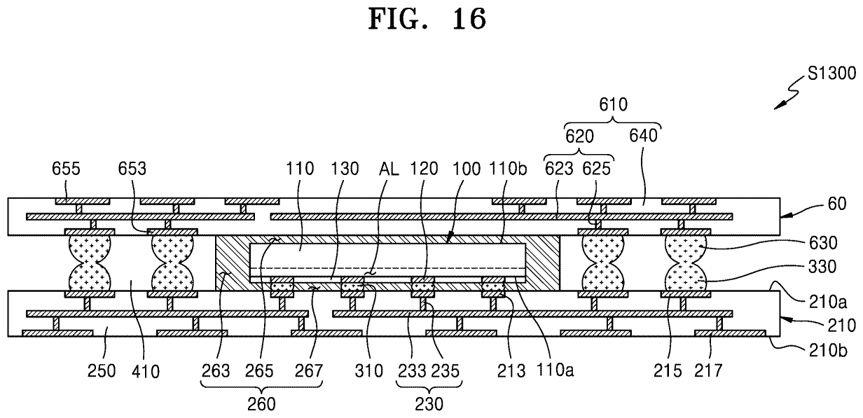

In an example embodiment, in a process of mounting the interposer 60 on the package substrate 210, an interposer connection terminal 630 (see FIG. 16) of the interposer 60 may be combined to and integrated with the conductive pillar 330 of the semiconductor package 10.

The semiconductor package 10 according to an example embodiment of the inventive concept may provide the adhesive layer 260 including: a first adhesive portion 263 interposed between the semiconductor chip 100 and the package substrate 210 and providing adhesion between the semiconductor chip 100 and the package substrate 210; and a third adhesive portion 267 interposed between the semiconductor chip 100 and the interposer substrate 610 and providing adhesion between the semiconductor chip 100 and the interposer substrate 610.

In addition, the adhesive layer 260 may include a material that becomes soft but does not completely dissolve or melt when heat is applied thereto. Therefore, in a process of forming the adhesive layer 260, a space between the semiconductor chip 100 and the package substrate 210 and a space between the semiconductor chip 100 and the interposer substrate 610 may be filled with the adhesive layer 260 without voids.

Accordingly, the structural reliability between the semiconductor chip 100 and the package substrate 210 and the structural reliability between the semiconductor chip 100 and the interposer substrate 610 may be improved.

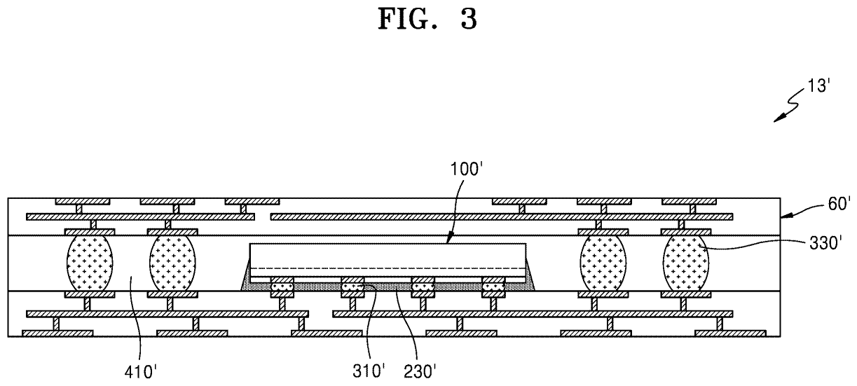

FIG. 3 is a cross-sectional view of a semiconductor package 13′ according to a comparative example.

The semiconductor package 13′ according to the comparative example may include a package substrate 210′, a semiconductor chip 100′, an underfill member 230′, a chip connection terminal 310′, a conductive pillar 330′, a molding layer 410′, an interposer 60′, and the like.

Referring to FIG. 3, the underfill member 230′ may be arranged between the semiconductor chip 100′ and the package substrate 210′. In detail, after the semiconductor chip 100′ is arranged on the package substrate 210′, the underfill member 230′ may be arranged between the semiconductor chip 100′ and the package substrate 210′.

As the semiconductor package 13′ is designed to have a less thickness and less weight, a distance in a vertical direction between the semiconductor chip 100′ and the package substrate 210′ gradually decreases. Accordingly, in a process of injecting the underfill member 230′ between the semiconductor chip 100′ and the package substrate 210′, a space between the semiconductor chip 100′ and the package substrate 210′ may not be completely filled with the underfill member 230′, and voids may be formed in the space. That is, the structural reliability between the semiconductor chip 100′ and the package substrate 210′ may be weak.

In addition, as the semiconductor 13′ is designed to have a less thickness and less weight, a distance in a vertical direction between the semiconductor chip 100′ and the interposer 60′ gradually decreases. Accordingly, in a process of injecting the molding layer 410′ between the package substrate 210′ and the interposer 60′, a space between the package substrate 210′ and the interposer 60′ may not be completely filled with the molding layer 410′, and voids may be formed in the space. That is, the structural reliability between the semiconductor chip 100′ and the interposer 60′ may be weak.

However, the semiconductor package 10 described with reference to FIGS. 1 and 2 may include the adhesive layer 260 that includes a material that becomes soft but does not completely dissolve or melt when heat is applied thereto. Accordingly, in a process of forming the adhesive layer 260 (see FIG. 1) on the package substrate 210 (see FIG. 1), the space between the semiconductor chip 100 and the package substrate 210 and the space between the semiconductor chip 100 and the interposer substrate 610 may be filled with the adhesive layer 260 without voids. That is, the structural reliability between the semiconductor chip 100 and the package substrate 210 and the structural reliability between the semiconductor chip 100 and the interposer substrate 610 may be improved.

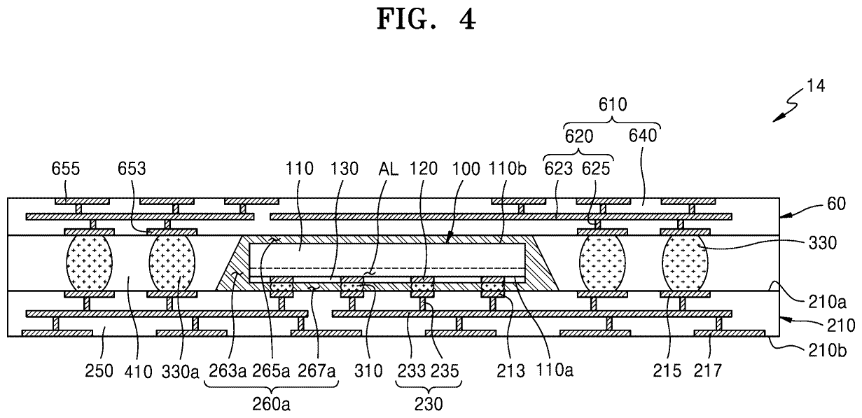

FIG. 4 is a cross-sectional view of a semiconductor package 14 according to an example embodiment of the inventive concept.

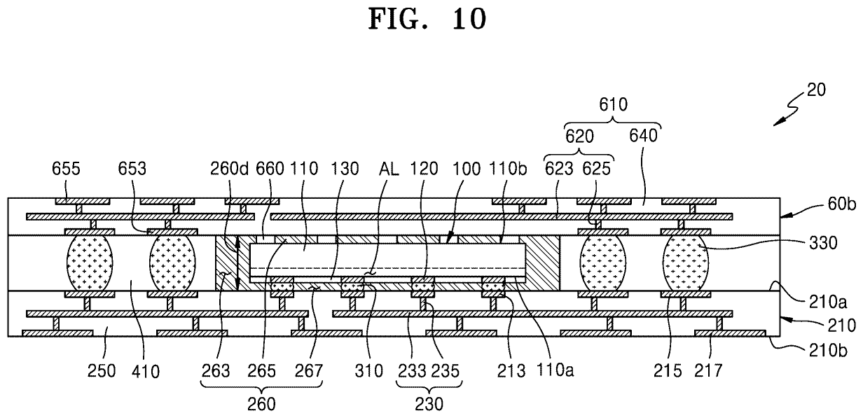

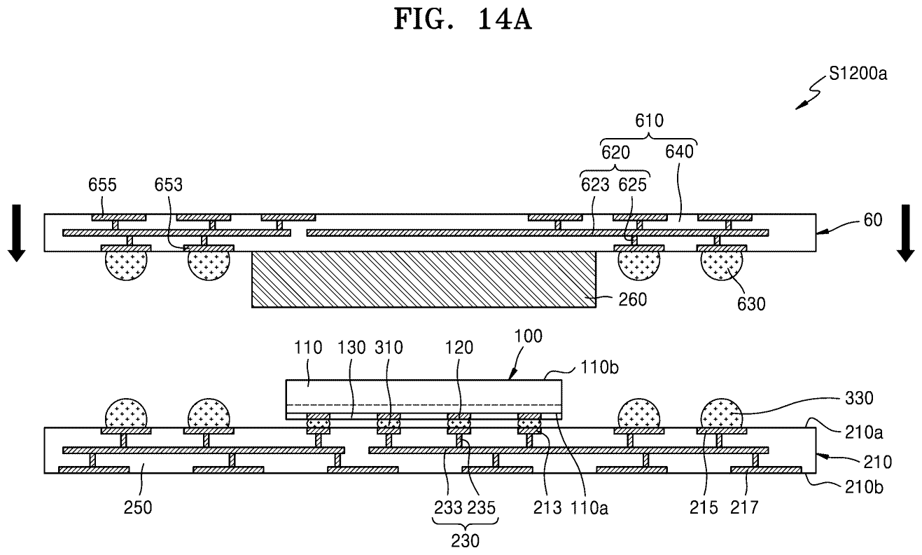

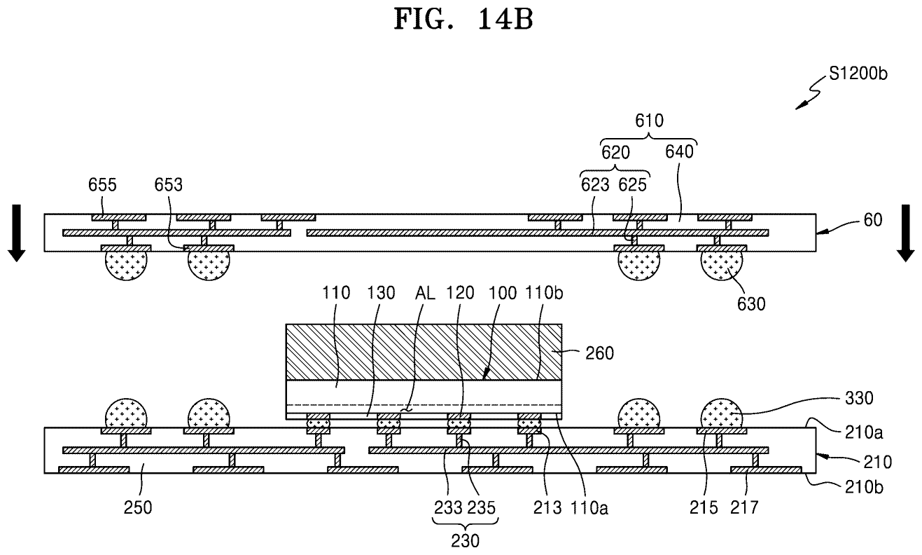

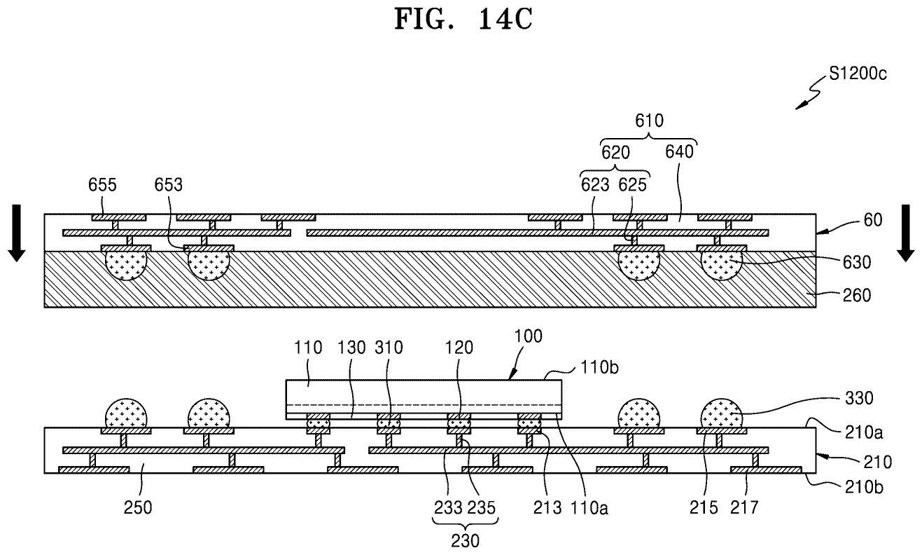

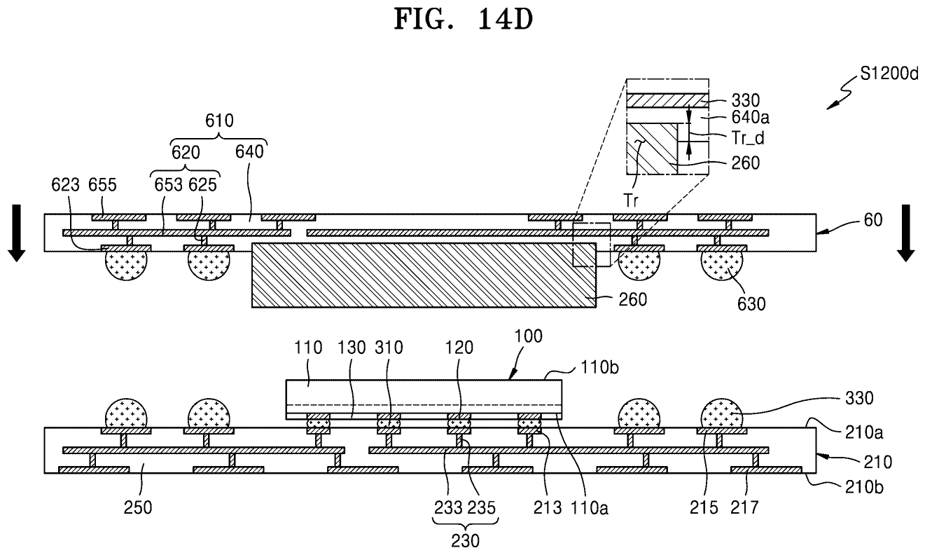

Hereinafter, repeated descriptions regarding the semiconductor package 10 of FIG. 10 and the semiconductor package 14 of FIG. 14 are omitted, and differences therebetween will be mainly described.

Referring to FIG. 4, the semiconductor package 14 may include the package substrate 210, the semiconductor chip 100, an adhesion layer 260a, the chip connection terminal 310, the conductive pillar 330, the molding layer 410, the interposer 60, and the like.

The adhesion layer 260a may include: a first adhesion portion 263a arranged between the bottom surface of the semiconductor chip 100 and the top surface 210a of the package substrate 210 and surrounding the chip connection terminal 310; a second adhesive portion 265a arranged at the outside of the side of the semiconductor chip 100; and a third adhesive portion 267a arranged between the top surface of the semiconductor chip 100 and the bottom surface of the interposer substrate 610.

In an example embodiment, the second adhesive portion 265a may have a tapered shape of which a cross-sectional area in a horizontal direction decreases away from the package substrate 210 in a vertical direction. For example, the adhesive layer 260a may have a truncated cone shape or quadrangular pyramid shape. In addition, a cross-section in a vertical direction of the adhesion layer 260a may have a trapezoid shape of which a length of a top edge is less than a length of a bottom edge.

In addition, a boundary surface between the adhesion layer 260a and the molding layer 410 may be arranged between a conductive pillar 330a closest to the semiconductor chip 100 from among the plurality of conductive pillars 330 and the side of the semiconductor chip 100. In addition, the boundary surface may incline from the top surface 210a of the package substrate 210.

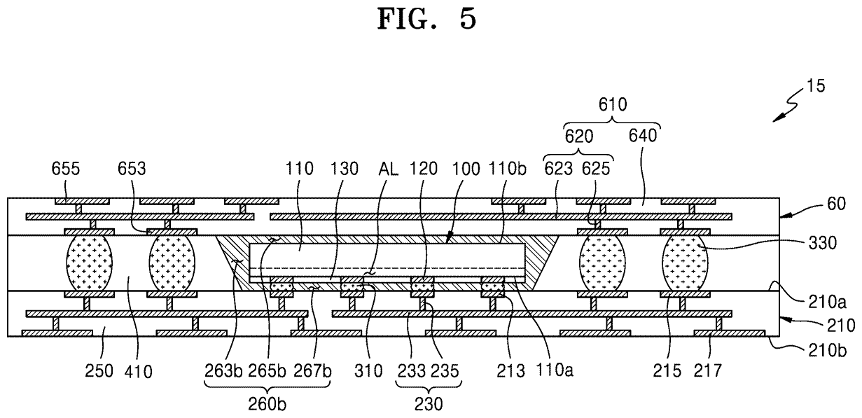

FIG. 5 is a cross-sectional view of a semiconductor package 15 according to an example embodiment of the inventive concept.

Hereinafter, repeated descriptions regarding the semiconductor package 10 of FIG. 1 and the semiconductor package 15 of FIG. 5 are omitted, and differences therebetween will be mainly described.

Referring to FIG. 5, the semiconductor package 15 may include the package substrate 210, the semiconductor chip 100, an adhesive layer 260b, the chip connection terminal 310, the conductive pillar 330, the molding layer 410, the interposer 60, and the like.

The adhesive layer 260b may include: a first adhesive portion 263b arranged between the bottom surface of the semiconductor chip 100 and the top surface 210a of the package substrate 210 and surrounding the chip connection terminal 310; a second adhesive portion 265b arranged at the outside of the side of the semiconductor chip 100; and a third adhesive portion 267b arranged between the top surface of the semiconductor chip 100 and the bottom surface of the interposer substrate 610.

In an example embodiment, the second adhesive portion 265b may have a tapered shape of which a cross-sectional area in the horizontal direction increases away from the package substrate 210 in the vertical direction. For example, the adhesive layer 260b may have a reverse-truncated cone or a reverse-quadrangular pyramid shape. In addition, a cross-section of the adhesive layer 260b in the vertical direction may have a trapezoid shape of which a length of a top edge is greater than a length of a bottom edge.

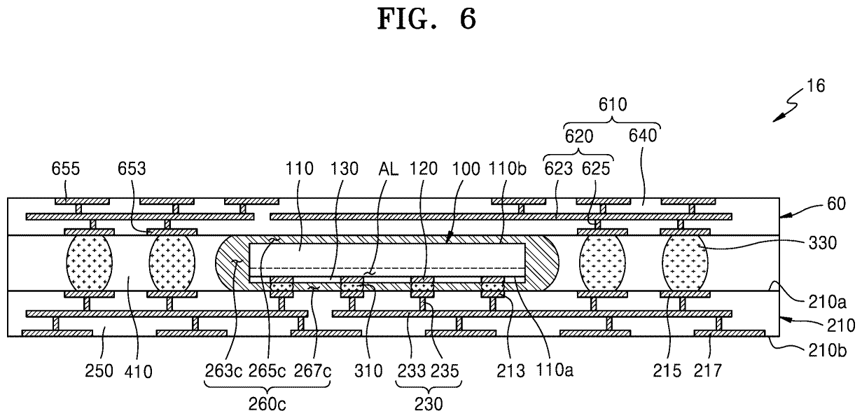

FIG. 6 is a cross-sectional view of a semiconductor package 16 according to an example embodiment of the inventive concept.

Hereinafter, repeated descriptions regarding the semiconductor package 10 of FIG. 1 and the semiconductor package 16 of FIG. 6 are omitted, and differences therebetween will be mainly described.

Referring to FIG. 6, the semiconductor package 16 may include the package substrate 210, the semiconductor chip 100, an adhesive layer 260c, the chip connection terminal 310, the conductive pillar 330, the molding layer 410, the interposer 60, and the like.

The adhesive layer 260c may include: a first adhesive portion 263c arranged between the bottom surface of the semiconductor chip 100 and the top surface 210a of the package substrate 210 and surrounding the chip connection terminal 310; a second adhesive portion 265c arranged at the outside of the side of the semiconductor chip 100; and a third adhesive portion 267c arranged between the top surface of the semiconductor chip 100 and the bottom surface of the interposer substrate 610.

In an example embodiment, the second adhesive portion 265c may have a jar shape of which a cross-sectional area in the horizontal direction first increases and then decreases away from the package substrate 210 in the vertical direction.

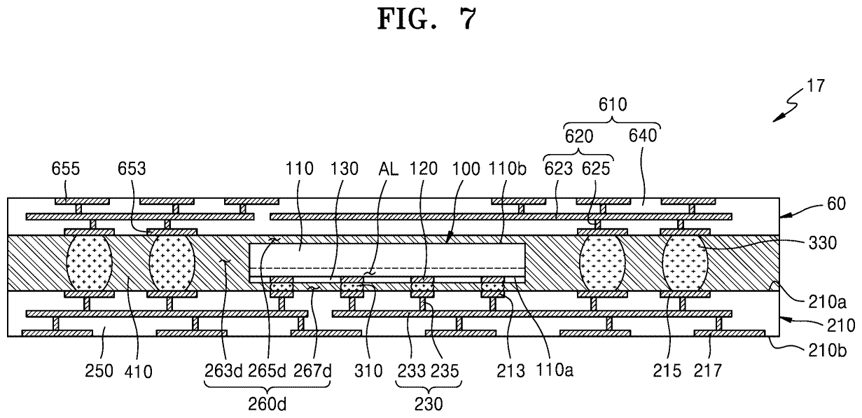

FIG. 7 is a cross-sectional view of a semiconductor package 17 according to an example embodiment of the inventive concept.

Hereinafter, repeated descriptions regarding the semiconductor package 10 of FIG. 1 and the semiconductor package 17 of FIG. 7 will be omitted, and differences therebetween will be mainly described.

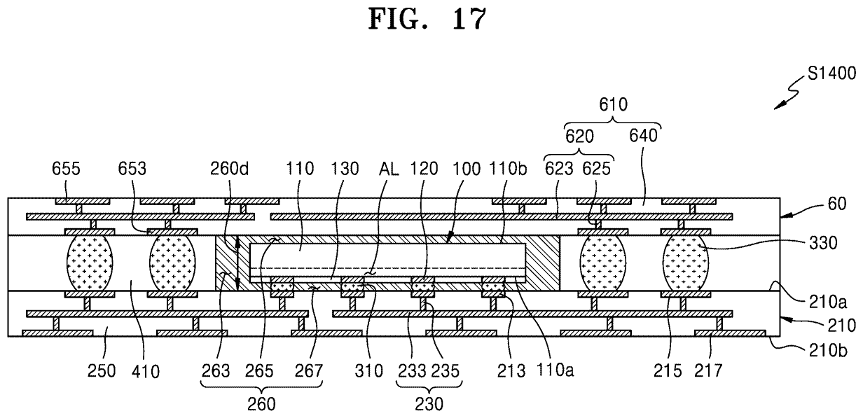

Referring to FIG. 17, the semiconductor package 17 may include the package substrate 210, the semiconductor chip 100, an adhesive layer 260d, the chip connection terminal 310, the conductive pillar 330, the interposer 60, and the like.

The adhesive layer 260d may include: a first adhesive portion 263d arranged between the bottom surface of the semiconductor chip 100 and the top surface 210a of the package substrate 210 and surrounding the chip connection terminal 310; a second adhesive portion 265d arranged at the outside of the side of the semiconductor chip 100 and surrounding the conductive pillar 330; and a third adhesive portion 267d arranged between the top surface of the semiconductor chip 100 and the bottom surface of the interposer substrate 610.

That is, the adhesive layer 260d of the semiconductor package 17 of FIG. 7 may be arranged between the package substrate 210 and the interposer 60 and fill a space between the package substrate 210 and the semiconductor chip 100 and a space between the semiconductor chip 100 and the interposer 60. In addition, the adhesive layer 260d may cover the conductive pillar 330 at the outside of the semiconductor chip 100.

In an example embodiment, a side of the adhesive layer 260d may be on a same plane as the side of the interposer substrate 610 and the side of the package substrate 210. In addition, a length in a horizontal direction of the adhesive layer 260d may be substantially identical to a length in a horizontal direction of the package substrate 210 and a length in a vertical direction of the interposer substrate 610, and a length in a vertical direction of the adhesive layer 260d may be substantially identical to a length in a vertical direction of the conductive pillar 330.

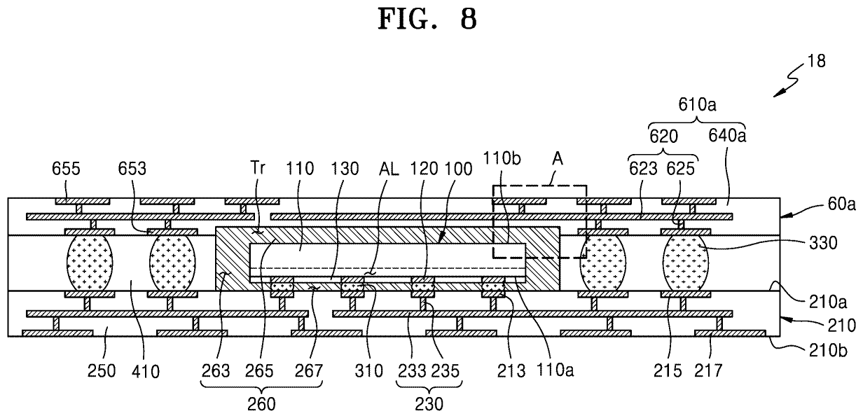

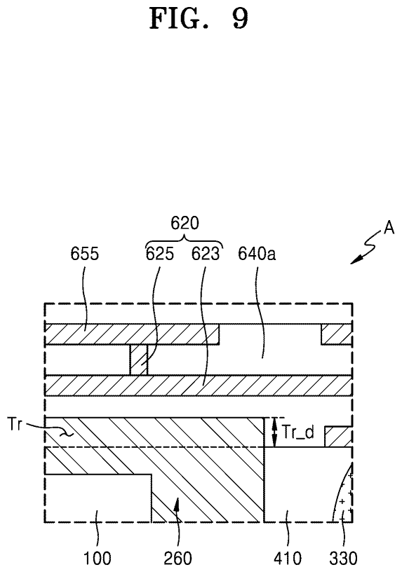

FIG. 8 is a cross-sectional view of a semiconductor package 18 according to an example embodiment of the inventive concept. FIG. 9 is an enlarged view of a region marked with “A” shown in FIG. 8.

Hereinafter, repeated descriptions regarding the semiconductor package 10 of FIG. 1 and the semiconductor package 18 of FIG. 8 will be omitted, and differences therebetween will be mainly described.

Referring to FIGS. 8 and 9, an interposer 60a of the semiconductor package 18 may include an interposer substrate 610a, the first interposer substrate pad 653, and the second interposer substrate pad 655. In addition, the interposer substrate 610a may include the interposer substrate pattern 620 and an interposer insulating layer 640a surrounding the interposer substrate pattern 620.

In an example embodiment, the interposer 60a may include, at a bottom portion thereof, a trench Tr accommodating at least a portion of the adhesive layer 260. The trench Tr of the interposer 60a may include a groove that is provided in a bottom surface of the interposer substrate 610a and concavely formed in a direction facing the top surface of the interposer substrate 610a.

In an example embodiment, a cross-section in a horizontal direction of the trench Tr of the interposer 60a may have a square or round shape. However, the shape of the cross-section in the horizontal direction of the trench Tr of the interposer 60a is not limited to the shape stated above.

In addition, a depth tr_d in a vertical direction of the trench Tr of the interposer 60a may be from about 5 micrometers to about 100 micrometers. In addition, a depth in the vertical direction of the trench Tr of the interposer 60a may be less than the length in the vertical direction of the adhesive layer 260. For example, the depth Tr_d in the vertical direction of the trench Tr of the interposer may be from about 5% to about 20% of the length in the vertical direction of the adhesive layer 260.

As the interposer 60a may have the trench Tr in the bottom portion thereof, the interposer substrate 610a of the interposer 60a may surround at least a portion of the adhesive layer 260. In addition, the length in the vertical direction of the adhesive layer 260 may be greater than the length in the vertical direction of the molding layer 410.

As the interposer 60a may have the trench Tr that accommodates at least a portion of the adhesive layer 260, a gap in the vertical direction between the interposer 60a and the semiconductor chip 100 may increase, and a thickness of the adhesive layer 260 that fills the gap may increase. In accordance with increase in the thickness of the adhesive layer 260 arranged between the interposer 60a and the semiconductor chip 100, the structural reliability between the interposer 60a and the semiconductor chip 100 may be improved.

In addition, as inner surfaces of the interposer substrate 610a defining the trench Tr of the interposer 60a may support a portion of the side of the adhesive layer 260, the structural reliability of the adhesive layer 260 may be improved.

FIG. 10 is a cross-sectional view of a semiconductor package 20 according to an example embodiment of the inventive concept.

Hereinafter, repeated descriptions regarding the semiconductor package 10 of FIG. 1 and the semiconductor package 20 of FIG. 10 will be omitted, and differences therebetween will be mainly described.

Referring to FIG. 10, an interposer 60b of the semiconductor package 20 may include the interposer substrate 610, the first interposer substrate pad 653, the second interposer substrate pad 655, and an interposer patch 660.

The interposer patch 660 may protrude from the bottom surface of the interposer substrate 610. In addition, the interposer patch 660 may be between the bottom surface of the interposer substrate 610 and the top surface of the semiconductor chip 100. For example, in a process of mounting the interposer 60b on the package substrate 210, the interposer patch 660 may be in contact with the top surface of the semiconductor chip 100.

In an example embodiment, the interposer patch 660 may have a concavo-convex shape of which concavity and convexity repeatedly appear. In addition, a material of the interposer patch 660 may be substantially identical to the material of the interposer insulating layer 640. For example, the material of the interposer patch 660 may include an oxide or a nitride.

In an example embodiment, in the process of mounting the the interposer 60b on the package substrate 210, the interposer patch 660 may function as a damper that reduces an intensity of a physical conflict between the semiconductor chip 100 and the interposer 60b. In addition, in the process of mounting the interposer 60b on the package substrate 210, the interposer patch 660 may be configured to prevent inclination of the the interposer 60b?.

In an example embodiment, a plurality of the interposer patches 660 may be provided, and the plurality of interposer patches 660 may be separately arranged in the horizontal direction. A portion of the adhesive layer 260 may be arranged between the semiconductor chip 100 and the interposer 60b and surround the interposer patch 660.

FIG. 11 is a cross-sectional view of a semiconductor package 1 according to an example embodiment of the inventive concept.

The semiconductor package 1 of FIG. 11 is a package-on-package (POP) type semiconductor package including a lower semiconductor package 10 and the upper semiconductor package 90. In detail, the semiconductor package 1 may have a structure in which the upper semiconductor package 90 is mounted on the semiconductor package 10 described with reference to FIG. 1.

The lower semiconductor package 10 may include the package substrate 210, the lower semiconductor chip 100, the adhesive layer 260, the chip connection terminal 310, the conductive pillar 330, the lower molding layer 410, an external connection terminal 510, the interposer 60, and the like. The inventive concept regarding the lower semiconductor package 10 is the same as the descriptions with reference to FIG. 1, and therefore, details thereof are omitted.

The external connection terminal 510 may include a terminal connected to the third package substrate pad 217 of the package substrate 210 and configured to connect the package substrate 210 to an external device. The external connection terminal 510 may include a metal material including at least any one of Ag, Cu, and Al.

The semiconductor package 1 of FIG. 11 may include technical idea of the lower semiconductor package 10 described with reference to FIG. 1. However, the semiconductor package 1 is not limited thereto and may include technical idea regarding lower semiconductor packages described with reference to FIGS. 4 to 10.

The upper semiconductor package 90 may include an upper semiconductor chip 1000, a redistribution structure 1100, an upper molding layer 1200, a package connection terminal 1300, and the like.

In an example embodiment, the upper semiconductor chip 1000 may be mounted on the redistribution structure 1100. A plurality of the upper semiconductor chips 1000 may be provided. For example, the upper semiconductor chip 1000 may include a first upper semiconductor chip 1000a and a second upper semiconductor chip 1000b arranged on the first semiconductor chip 1000a.

In an example embodiment, the second upper semiconductor chip 1000b may be mounted on a top surface of the first upper semiconductor chip 1000a. For example, the second upper semiconductor chip 1000b may be attached on the top surface of the first semiconductor chip 1000a through an adhesive material such as an adhesive film.

In addition, the first upper semiconductor chip 1000a and the second upper semiconductor chip 1000b may be electrically connected to each other through a conductive wire w. However, the first upper semiconductor chip 1000a and the second upper semiconductor chip 1000b are not limited thereto, and may be electrically connected to each other through a penetration electrode.

In an example embodiment, the first upper semiconductor chip 1000a and the second upper semiconductor chip 1000b may each include a logic semiconductor chip. The logic semiconductor chip may include, for example, a logic semiconductor chip such as central processor unit (CPU), micro processor unit (MPU), graphic processor unit (GPU), or application processor (AP).

In addition, the first upper semiconductor chip 1000a and the second upper semiconductor chip 1000b may each include a memory semiconductor chip. The memory semiconductor chip may include, for example, a volatile memory semiconductor chip such as dynamic random access memory (DRAM) or static random access memory (SRAM), and may also include a non-volatile memory semiconductor chip such as phase-change random access memory (PRAM), magneto-resistive random access memory (MRAM), ferroelectric random access memory (FeRAM), or resistive random access memory (RRAM).

A redistribution structure 1100 may include a redistribution pattern 1120, a redistribution insulating layer 1140, a first redistribution pad 1170, a second redistribution pad 1190, and the like. In an example embodiment, the redistribution pattern 1120 may include a redistribution line pattern 1123 extending in a horizontal direction in the redistribution insulating layer 1140 and a redistribution via pattern 1125 extending in a vertical direction in the redistribution insulating layer 1140.

In an example embodiment, a material of the redistribution pattern 1120 may include Cu. However, the material of the redistribution pattern 1120 is not limited thereto and may include a metal such as Ni, Au, Ag, Al, W, Ti, Ta, In, Mo, Mn, Co, Sn, Mg, Re, Be, Ga, and Ru, or an alloy thereof.

The redistribution insulating layer 1140 may surround the redistribution pattern 1120. In an example embodiment, the material of the redistribution insulating layer 1140 may also include an oxide or a nitride. For example, the redistribution insulating layer 1140 may include silicon oxide or silicon nitride.

In an example embodiment, the first redistribution pad 1170 may be a pad arranged on a top surface of the redistribution structure 1100 and configured to electrically connect the first upper semiconductor chip 1000a and the second upper semiconductor chip 1000b to the redistribution patter 1120.

In an example embodiment, the first upper semiconductor chip 1000a and the second upper semiconductor chip 1000b may be connected to the redistribution structure 1100 through the conductive wire w. In further detail, the conductive wire w may connect a chip pad 1020a of the first upper semiconductor chip 1000a to the first redistribution pad 1170 of the redistribution structure 1100, and may connect a chip pad 1020b of the second upper semiconductor chip 1000b to the first redistribution pad 1170 of the redistribution structure 1100.

In an example embodiment, the second redistribution pad 1190 may include a pad arranged on a bottom surface of the redistribution structure 1100, the pad on which the package connection terminal 1300 is mounted.

In an example embodiment, the upper molding layer 1200 may surround the upper semiconductor chip 1000 on the redistribution structure 1100. The upper molding layer 1200 may include an underfill material including at least any one of an insulating polymer and an epoxy resin. For example, the upper molding layer 1200 may include an epoxy molding compound (EMC).

In an example embodiment, a side of the upper molding layer 1200 of the upper semiconductor package 90 and a side of the redistribution structure 1100 may be on a same plane. In addition, a side of the upper semiconductor package 90 and a side of the lower semiconductor package 10 may be on a same plane.

The package connection terminal 1300 may include a connection terminal arranged between the interposer 60 and the redistribution structure 1100 and configured to electrically connect the upper semiconductor chip 1000 to the interposer 60. For example, the package connection terminal 1300 may include a solder ball of a metal material including at least any one of Sn, Ag, Cu, and Al.

In an example embodiment, the package connection terminal 1300 may electrically connect the second redistribution pad 1190 of the redistribution structure 1100 to the second interposer substrate pad 655 of the interposer 60.

The semiconductor package 1 according to an example embodiment may include the adhesive layer 260 including: the first adhesive portion 263 arranged between a lower semiconductor chip 100 and the package substrate 210 and providing adhesion between the lower semiconductor chip 100 and the package substrate 210; and the third adhesive portion 267 arranged between the lower semiconductor chip 100 and the interposer substrate 610 and providing adhesion between the lower semiconductor chip 100 and the interposer substrate 610.

In addition, the adhesive layer 260 may include a material that becomes soft but does not completely dissolve or melt when heat is applied thereto. Therefore, in a process of forming the adhesive layer 260 on the package substrate 210, a space between the lower semiconductor chip 100 and the package substrate 210 and a space between the lower semiconductor chip 100 and the interposer substrate 610 may be filled with the adhesive layer 260, without voids.

Accordingly, the structural reliability between the lower semiconductor chip 100 and the package substrate 210 and the structural reliability between the lower semiconductor chip 100 and the interposer substrate 610 may be improved.

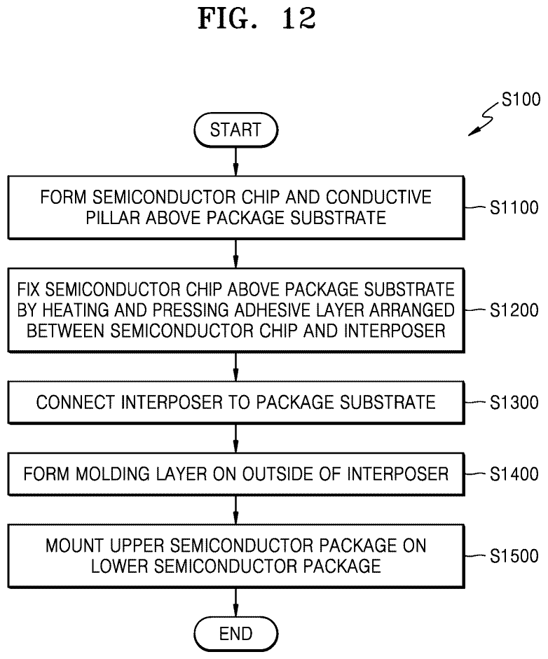

Hereinafter, a manufacturing method of a semiconductor package according to an example embodiment of the inventive concept will be described in detail with reference to FIGS. 12 to 18. The manufacturing method of the semiconductor package of the inventive concept may include a manufacturing method of the semiconductor package 1 of POP type described with reference to FIG. 11.

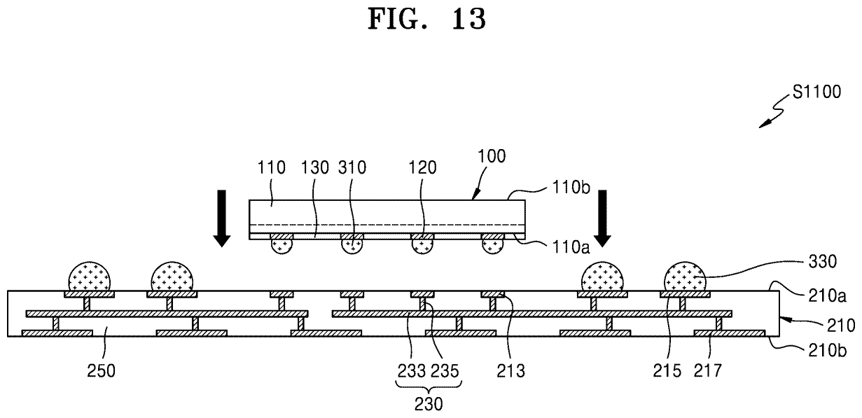

FIG. 12 is a flowchart of a manufacturing method (S100) of the semiconductor package 1 according to an example embodiment of the inventive concept. FIG. 13 through FIG. 18 are diagrams showing processes of the manufacturing method (S100) of the semiconductor package 1 according to an example embodiment of the inventive concept.

Referring to FIG. 12, the manufacturing method of the semiconductor package 1 (S100) according to an example embodiment of the inventive concept may include: forming the semiconductor chip 100 and the conductive pillar 330 on the package substrate 210 (S1100); heating and pressing the adhesive layer 260 arranged between the semiconductor chip 100 and the interposer 60 and fixing the semiconductor chip 100 above the package substrate 210 through the adhesive layer 260 (S1200); connecting the interposer 60 to the package substrate 210 (S1300); forming the molding layer 410 at the outside of the adhesive layer 260 (S1400); and mounting the upper semiconductor package 90 on the lower semiconductor package 10 (S1500).

FIG. 13 is a diagram showing a process of forming the semiconductor chip 100 and the conductive pillar 330 on the package substrate 210.

Referring to FIGS. 12 and 13, the manufacturing method (S100) of the semiconductor package 1 according to an example embodiment of the inventive concept may include forming the semiconductor chip 100 and the conductive pillar 330 on the package substrate 210 (S1100).

Operation S1100 may include: mounting the semiconductor chip 100 in a center portion of the semiconductor chip 100; and forming the conductive pillar 330 at an edge portion of the package substrate 210.

The mounting of the semiconductor chip 100 on the package substrate 210 may include electrically connecting the semiconductor chip 100 to the package substrate 210 through a flip-chip bonding process. In detail, the semiconductor chip 100 may be mounted on the package substrate 210 such that the chip connection terminal 310 attached to the bonding surface of the chip pad 120 of the semiconductor chip 100 contacts the first package substrate pad 213 of the package substrate 210.

In addition, the forming of the conductive pillar 330 on the package substrate 210 may include mounting the conductive pillar 330 on the package substrate 210 such that a bottom surface of the conductive pillar 330 contacts the second package substrate pad 215 of the package substrate 210.

FIGS. 14A to 14D and 15 are diagrams of operation S1200 of heating and pressing the adhesive layer 260 arranged between the semiconductor chip 100 and the interposer 60 and fixing the semiconductor chip 100 on the package substrate 210 through the adhesive layer 260.

Referring to FIG. 14, operation S1200a may include attaching the adhesive layer 260 to a bottom portion of the interposer substrate 610. For example, the adhesive layer 260 may be attached to the bottom surface of the interposer substrate 610 that overlaps in the vertical direction with the semiconductor chip 100 but does not overlap in the vertical direction with the conductive pillar 330. In addition, a length in the horizontal direction of the adhesive layer 260 attached to the interposer substrate 610 may be greater than the length in the horizontal direction of the semiconductor chip 100.

In an example embodiment, the adhesive layer 260 may include a material that becomes soft but does not completely dissolve or melt when heat is applied thereto. In addition, the adhesive layer 260 may include a DAF that becomes soft but does not completely dissolve or melt when heat is applied thereto. When the adhesive layer 260 includes the DAF, the adhesive layer 260 may be attached to the bottom surface of the interposer substrate 610 by taping.

When the interposer substrate 610 moves downward to heat and press the adhesive layer 260 arranged between the interposer substrate 610 and the semiconductor chip 100, the adhesive layer 260 may become soft but does not completely dissolve or melt.

Accordingly, the adhesive layer 260 may flow in a direction toward the package substrate 210. In addition, the adhesive layer 260 may fill the space between the package substrate 210 and the semiconductor chip 100 and surround the chip connection terminal 310.

Due to fluidity of the adhesive layer 260, like the adhesive layer 260a described with reference to FIG. 4, the adhesive layer 260 may be formed in a tapered shape of which a cross-sectional area in the horizontal direction decreases away from the package substrate 210. However, the embodiment is not limited thereto, and when the fluidity of the adhesive layer 260 is relatively low, like the adhesive layer 260 described with reference to FIG. 1, the direction in which the side of the adhesive layer 260 extends may be perpendicular to the direction in which the top surface 210a of the package substrate 210 extends.

Referring to FIG. 14B, operation S1200b may include attaching the adhesive layer 260 to the top surface of the semiconductor chip 100. The length in the vertical direction of the adhesive layer 260 attached to the top surface of the semiconductor chip 100 may be greater than a length in the vertical direction of the semiconductor chip 100. In addition, the length in the horizontal direction of the adhesive layer 260 may be substantially identical to the length in the horizontal direction of the semiconductor chip 100. That is, the side of the adhesive layer 260 may be on a same plane as the side of the semiconductor chip 100.

When the interposer substrate 610 moves downward to heat and press the adhesive layer 260 arranged between the interposer substrate 610 and the semiconductor chip 100, the adhesive layer 260 may become soft but does not completely dissolve or melt.

When the adhesive layer 260 is pressed by the interposer substrate 610, the adhesive layer 260 may expand from the space between the semiconductor chip 100 and the interposer substrate 610 to the outside of the semiconductor chip 100. In addition, a portion of the adhesive layer 260 may flow in a direction toward the package substrate 210 and fill the space between the package substrate 210 and the semiconductor chip 100. In this case, like the adhesive layer 260b (see FIG. 5) described with reference to FIG. 5, the adhesive layer 260 may be formed in a tapered shape of which a cross-sectional area in the horizontal direction increases away from the package substrate 210.

Referring to FIG. 14, operation S1200c may include attaching the adhesive layer 260 to the bottom portion interposer substrate 610. For example, the adhesive layer 260 may be attached to the bottom surface of the interposer substrate 610 to overlap in the vertical direction with the semiconductor chip 100 and the conductive pillar 330.

In addition, the length in the vertical direction of the adhesive layer 260 attached to the interposer substrate 610 may be greater than the length in the vertical direction of the semiconductor chip 100, and the length in the horizontal direction of the adhesive layer 260 may be substantially identical to the length in the horizontal direction of the semiconductor chip 100. For example, the side of the adhesive layer 260 may be on a same plane as the side of the interposer substrate 610.

When the interposer substrate 610 moves downward to heat and press the adhesive layer 260 arranged between the interposer substrate 610 and the semiconductor chip 100, the adhesive layer 260 may fill the space between the package substrate 210 and the semiconductor chip 100, thereby surrounding the chip connection terminal 310 and the conductive pillar 330 arranged at the outside of the semiconductor chip 100.

The adhesive layer 260 of the semiconductor package manufactured according to the manufacturing method shown in FIG. 14C may cover the conductive pillar 330 at the outside of the semiconductor chip 100, like the adhesive layer 260 (see FIG. 7) shown in FIG. 7.

Referring to FIG. 14D, operation S1200d may include attaching the adhesive layer 260 to a bottom portion of an interposer substrate 610. For example, a portion of the adhesive layer 260 may be accommodated in the trench Tr provided in the bottom portion of the interposer substrate 610. For example, the adhesive layer 260 may be attached to inner surfaces of the interposer 610 that define the trench Tr.

As the interposer 60 may have the trench Tr accommodating at least a portion of the adhesive layer 260, the gap in the vertical direction between the interposer 60 and the semiconductor chip 100 may increase, and the thickness of the adhesive layer 260 filling the gap may also increase. In accordance with the increase in the thickness of the adhesive layer 260 arranged between the interposer 60 and the semiconductor chip 100, the structural reliability between the interposer 60 and the semiconductor chip 100 may be improved.

In addition, as the inner surfaces of the interposer 60 defining the trench Tr of the interposer 60 may support the adhesive layer 260 arranged in the trench Tr, escape of the adhesive layer 260 may be prevented in operation S1200d.

Referring to FIG. 15, when the interposer 60 moves downward, the adhesive layer 260 arranged between the semiconductor chip 100 and the interposer 60 may be pressed and heated. When the adhesive layer 260 is heated, the adhesive layer 260 may become soft but does not being completely dissolve or melt.

In a process in which the interposer 60 presses the adhesive layer 260, the adhesive layer 260 may fill a space between the interposer 60 and the semiconductor chip 100. In addition, when the interposer 60 continually moves downward, the adhesive layer 260 may flow in the direction facing the package substrate 210, and may fill the space between the package substrate 210 and the semiconductor chip 100.

FIG. 16 is a drawing of operation S1300 to connect the interposer 60 to the package substrate 210.

Referring to FIG. 16, operation S1300 may include connecting the interposer connection terminal 630 of the interposer 60 to the conductive pillar 330 mounted on the package substrate 210. In operation S1300, the interposer connection terminal 630 and the conductive pillar 330 may be integrated. Accordingly, the interposer 60 and the package substrate 210 may be electrically connected to each other through the conductive pillar 330.

FIG. 17 is a diagram of operation S1400 to form the molding layer 410 at the outside of the adhesive layer 260.

Referring to FIG. 17, operation S1400 may include injecting the molding layer 410 into the space between the package substrate 210 and the interposer 60. The molding layer 410 injected between the package substrate 210 and the interposer 60 may surround the side of the adhesive layer 260. In addition, the molding layer 410 may be configured to fix the interposer 60 above the package substrate 210.

Manufacturing of the semiconductor package 10 described with reference to FIG. 1 may be completed through operations of the manufacturing method of the semiconductor package shown in FIGS. 13 to 17. The semiconductor package 10 may function as a lower semiconductor package in a PoP type semiconductor package including a lower semiconductor package and an upper semiconductor package.

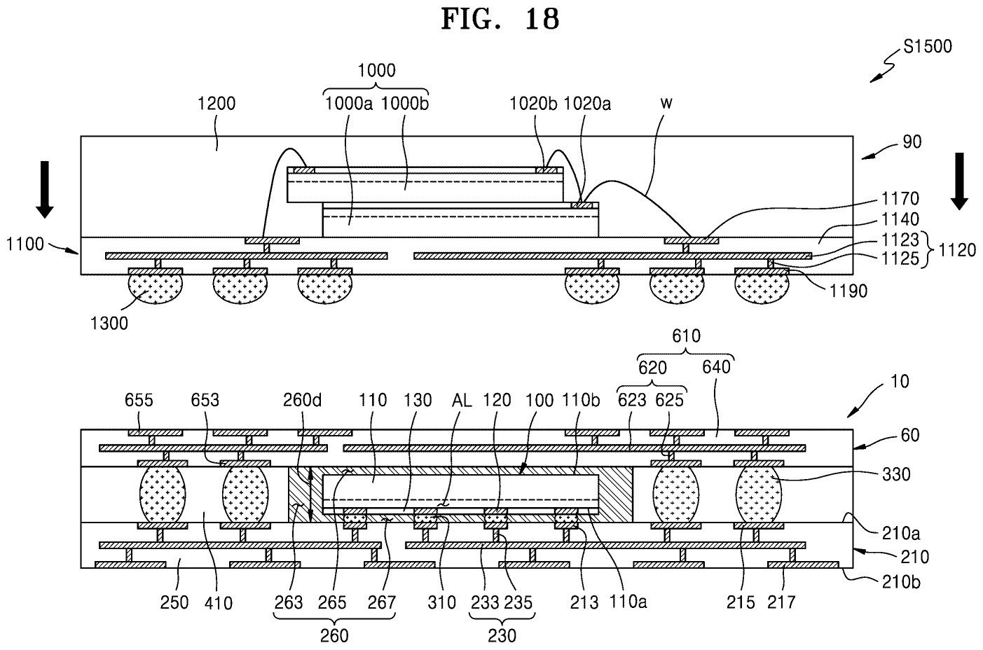

FIG. 18 is a diagram of operation S1500 to mount the upper semiconductor package 90 on the interposer 60 of the lower semiconductor package 10.

Referring to FIG. 18, operation S1500 may include mounting the upper semiconductor package 90 above the interposer 60 such that the package connection terminal 1300 contacts the second interposer substrate pad 655 of the interposer 60.

As the manufacturing method S100 of the semiconductor package 1 according to an example embodiment of the inventive concept may include heating and pressing the adhesive layer 260, the space between the semiconductor chip 100 and the package substrate 210 and the space between the semiconductor chip 100 and the interposer substrate 610 may be filled with the adhesive layer 260 without voids.

Accordingly, the structural reliability between the semiconductor chip 100 and the package substrate 210 of the semiconductor package 1 according to an example embodiment of the inventive concept and the structural reliability between the semiconductor chip 100 and the interposer substrate 610 may be improved.

In addition, the manufacturing method of the semiconductor package 1 according to an example embodiment of the inventive concept may fix the semiconductor chip 100 and the package substrate 210 and fix the semiconductor chip 100 and the interposer 60 through one adhesive layer 260.

Accordingly, using the manufacturing method S100 of the semiconductor package 1 according to an example embodiment may decrease a manufacturing time period and reduce manufacturing cost of the semiconductor package. In addition, the semiconductor package 1 manufactured by the manufacturing method S100 of the semiconductor package 1 have a smaller thickness and weight.

While the inventive concept has been particularly shown and described with reference to embodiments thereof, it will be understood that various changes in form and details may be made therein without departing from the spirit and scope of the following claims.

What is claimed is:

1. A method of manufacturing a semiconductor package, the manufacturing method comprising:
forming a semiconductor chip and a conductive pillar above a package substrate;
fixing the semiconductor chip above the package substrate through an adhesive layer by heating and pressing the adhesive layer between the semiconductor chip and an interposer on the semiconductor chip;
connecting the interposer to the package substrate; and
forming a molding layer on the package substrate outside of the adhesive layer,
wherein a material of the molding layer differs from a material of the adhesive layer so that a boundary surface forms where the molding layer and the adhesive layer contact each other.

2. The manufacturing method of claim 1, wherein forming the semiconductor chip above the package substrate comprises:
mounting the semiconductor chip on the package substrate through a flip-chip process.

3. The manufacturing method of claim 1, wherein fixing the semiconductor chip above the package substrate through the adhesive layer comprises:
attaching the adhesive layer under the interposer;
pressing and heating the adhesive layer by a downward movement of the interposer wherein the adhesive layer flows into and fills a space between the semiconductor chip and the interposer; and
shaping the adhesive layer in the space between the semiconductor chip and the package substrate according to fluidity of the adhesive layer.

4. The manufacturing method of claim 3, wherein attaching the adhesive layer under the interposer comprises disposing at least a portion of the adhesive layer in a trench formed in a bottom portion of the interposer.

5. The manufacturing method of claim 4, wherein a depth of the trench of the interposer ranges from about 5 micrometers to about 100 micrometers.

6. The manufacturing method of claim 3, wherein attaching the adhesive layer under the interposer comprises attaching the adhesive layer under the interposer, wherein the adhesive layer has a vertical length that is greater than a vertical length of the semiconductor chip.

7. The manufacturing method of claim 3, wherein attaching the adhesive layer under the interposer comprises attaching the adhesive layer under the interposer, wherein the adhesive layer comprises a material that softens but does not completely dissolve or melt when heat is applied thereto.

8. The manufacturing method of claim 3, wherein attaching the adhesive layer under the interposer comprises attaching the adhesive layer under the interposer, wherein the adhesive layer comprises a die adhesive film (DAF).

9. The manufacturing method of claim 3, wherein attaching the adhesive layer under the interposer comprises attaching the adhesive layer under the interposer by taping.

10. The manufacturing method of claim 3, wherein attaching the adhesive layer under the interposer comprises attaching the adhesive layer under the interposer, wherein the adhesive layer is attached to a portion of the bottom surface of the interposer that overlaps the semiconductor chip in the vertical direction, but does not overlap the conductive pillar.

11. The manufacturing method of claim 3, wherein attaching the adhesive layer under the interposer comprises attaching the adhesive layer under the interposer, wherein the adhesive layer is attached to a portion of the bottom surface of the interposer that overlaps the semiconductor chip and the conductive pillar in the vertical direction.

12. The manufacturing method of claim 3, wherein shaping the adhesive layer in the space between the semiconductor chip and the package substrate comprises shaping the adhesive layer in the space between the semiconductor chip and the package substrate wherein the adhesive layer is formed to have a tapered shape of which a horizontal cross-sectional area decreases away from the package substrate.

13. The manufacturing method of claim 3, wherein shaping the adhesive layer in the space between the semiconductor chip and the package substrate comprises shaping the adhesive layer in the space between the semiconductor chip and the package substrate wherein the adhesive layer is formed to have a side which is perpendicular to an extension direction of a top surface of the package substrate.

14. A method of manufacturing a semiconductor package, the manufacturing method comprising:
forming a semiconductor chip and a conductive pillar above a package substrate;
attaching the adhesive layer onto the semiconductor chip;
preparing an interposer, pressing and heating the adhesive layer by a downward movement of the interposer wherein the adhesive layer flows into and fills a space between the semiconductor chip and the interposer;
shaping the adhesive layer in the space between the semiconductor chip and the package substrate according to fluidity of the adhesive layer, thereby fixing the semiconductor chip on the package substrate through the adhesive layer;
connecting the interposer to the package substrate; and
forming a molding layer on the package substrate outside of the adhesive layer,
wherein a material of the molding layer differs from a material of the adhesive layer so that a boundary surface forms where the molding layer and the adhesive layer contact each other.

15. The manufacturing method of claim 14, wherein forming the semiconductor chip above the package substrate comprises:
mounting the semiconductor chip on the package substrate through a flip-chip process.

16. The manufacturing method of claim 14, wherein attaching the adhesive layer onto the semiconductor chip comprises attaching the adhesive layer onto the semiconductor chip, wherein the adhesive layer has a vertical length that is greater than a vertical length of the semiconductor chip.

17. The manufacturing method of claim 14, wherein attaching the adhesive layer onto the semiconductor chip comprises attaching the adhesive layer onto the semiconductor chip, wherein the adhesive layer comprises a material that softens but does not completely dissolve or melt when heat is applied thereto.

18. The manufacturing method of claim 14, wherein shaping the adhesive layer in the space between the semiconductor chip and the package substrate comprises shaping the adhesive layer in the space between the semiconductor chip and the package substrate wherein the adhesive layer is formed in a tapered shape of which a cross-sectional area in the horizontal direction increases away from the package substrate.

19. A method of manufacturing a package-on-package (POP) type semiconductor package, the method comprising:
preparing a lower semiconductor package;
preparing an upper semiconductor package; and
mounting the upper semiconductor package on the lower semiconductor package,
wherein preparing the lower semiconductor package comprises:
forming a semiconductor chip and a conductive pillar above a package substrate;
fixing the semiconductor chip above the package substrate through an adhesive layer by heating and pressing the adhesive layer between the semiconductor chip and an interposer on the semiconductor chip;
connecting the interposer to the package substrate; and
forming a molding layer on the package substrate outside of the adhesive layer,
wherein a material of the molding layer differs from a material of the adhesive layer so that a boundary surface forms where the molding layer and the adhesive layer contact each other.

20. The manufacturing method of claim 19, wherein forming the semiconductor chip above the package substrate comprises:
mounting the semiconductor chip on the package substrate through a flip-chip process.
